(19) United States
(12) Patent Application Publication
(10) Pub. No.: US 2020/0312931 A1
(43) Pub. Date: Oct. 1, 2020

(54) DISPLAY PANEL, DISPLAY MODULE, AND FABRICATION METHOD THEREOF

(71) Applicant: Wuhan China Star Optoelectronics Semiconductor Display Technology Co., Ltd., Wuahn (CN)

(72) Inventors: Yangqi OU, Wuhan (CN); Min ZHENG, Wuhan (CN)

(73) Assignee: Wuhan China Star Optoelectronics Semiconductor Display Technology Co., Ltd., Wuhan (CN)

(21) Appl. No.: 16/492,155

(22) PCT Filed: May 15, 2019
(86) PCT No.: PCT/CN2019/086942

§ 371 Date: Sep. 9, 2019

(30) Foreign Application Priority Data
Mar. 27, 2019 (CN) 201910237933.5

(51) Int. Cl. H01L 27/32; H01L 29/786

(52) U.S. Cl. CPC H01L 27/3248; H01L 29/78633; H01L 27/3262; H01L 29/7869; H01L 29/78609

(57) ABSTRACT

A display panel, a display module, and a fabrication method thereof are provided. The display panel includes a display region, and at least two pixel units are disposed in the display region, and at least one first via hole is disposed between the adjacent two pixel units. The first via hole is disposed in an inorganic layer of the display panel.

### FIELD OF INVENTION

The present application relates to the field of display technologies, and more particularly to a display panel, a display module, and a fabrication method thereof.

### BACKGROUND

With development of technology, appearance of mobile electronic devices has undergone tremendous changes. Among them, flexible screens have attracted much attention due to their unique characteristics and huge potential. Compared with traditional screens, flexible screens are flexible and bendable, which can reduce the degree of accidental damage to the equipment and is much more durable than other screens.

However, cracks are generated due to stress concentration of a metal layer and an inorganic layer in the product when current flexible screens are bent, where the crack gradually extends toward the display region, resulting in failure of signal transmission and abnormal display on the screen.

### SUMMARY

The present application provides a display panel, a display module, and a fabrication method thereof to solve the technical problems such as abnormal image display during bending the existing flexible screen.

To solve the above problems, the technical solution provided by the present application is as follows:

An embodiment of the present application provides a display panel, comprising a display region;

wherein at least two pixel units are disposed in the display region, and at least one first via hole is disposed between the adjacent two pixel units; and

the first via hole is disposed in an inorganic layer of the display panel.

In the display panel of the present application, a substrate and a thin-film-transistor layer disposed over the substrate are disposed in the display region;

the thin-film-transistor layer comprises at least two thin-film-transistor units;

the two thin-film-transistor units respectively correspond to the pixel units;

the first via-hole is disposed between the two thin-film-transistor units; and

the first via-hole is filled with an organic material.

In the display panel of the present application, the adjacent two thin-film-transistor units comprises the at least one first via-hole therebetween.

In the display panel of the present application, the first via-hole is formed through the interlayer dielectric layer of the thin-film-transistor layer.

In the display panel of the present application, the first via-hole is formed through the interlayer dielectric layer and the gate insulating layer of the thin-film-transistor layer.

In the display panel of the present application,

the display panel further comprises a non-display region outside the display region;

the non-display region comprises a bending region, wherein a first recess is formed in the bending region; and

the first recess and the first via-hole are formed in the same etching process.

In the display panel of the present application,

the first recess is formed by a first etching process and a second etching process;

the first etching process removes the interlayer dielectric layer, the second gate insulating layer and the first gate insulating layer in the first recess; and

the second etching process removes the buffer layer and the stop layer.

An embodiment of the present application provides a method for fabricating a display panel, comprising:

providing a substrate, wherein an active layer, a gate insulating layer, a gate electrode layer, an interlayer dielectric layer, and a source/drain electrode layer are sequentially formed over the substrate;

performing an etching process to form at least one via-hole in at least one of the interlayer dielectric layer and the gate insulating layer;

forming a planarization layer over the interlayer dielectric layer;

wherein the first via-hole is disposed between adjacent two pixel units of the display panel.

In the method for fabricating a display panel of the present application, the display panel comprises a non-display region;

In the method for fabricating a display panel of the present application, the non-display region comprises a bending region, and a first recess is disposed in the bending region; and

a flexible organic material is filled in the first recess.

In the method for fabricating a display panel of the present application,

the first via-hole is formed through the interlayer dielectric layer as the first via-hole is formed above the interlayer dielectric layer, and the first via-hole and the first recess are formed by different etching processes.

In the method for fabricating a display panel of the present application, the first via-hole is formed through the interlayer dielectric layer and the gate insulating layer as the first via-hole is formed above the interlayer dielectric layer and the gate insulating layer, and the first via-hole and the first recess are formed in the same etching process.

In the method for fabricating a display panel of the present application, the display panel comprises a substrate and a thin-film-transistor layer disposed over the substrate;

the thin-film-transistor layer comprises at least two thin-film-transistor units;

the two thin-film-transistor units respectively correspond to the pixel elements;

the first via-hole is disposed between the two thin-film-transistor units; and

the first via-hole is filled with a flexible material.

In the method for fabricating a display panel of the present application, the first recess is formed by a first etching process and a second etching process;

the first etching process removes the interlayer dielectric layer, the second gate insulating layer and the first gate insulating layer in the first recess; and

the second etching process removes the buffer layer and the stop layer.

An embodiment of the present application also provides a display module, comprising a display panel, and a polarizing layer and a covering layer disposed above the display panel, wherein the display panel comprises a display region;

at least two pixel units are disposed in the display region, and

at least one first via hole is disposed between the adjacent two pixel elements, wherein the first via hole is disposed in an inorganic layer of the display panel.

In the display module of the present application, a substrate and a thin-film-transistor layer disposed over the substrate are disposed in the display region;

the thin-film-transistor layer comprises at least two thin-film-transistor units;

the two thin-film-transistor units respectively correspond to the pixel units;

the first via-hole is disposed between the two thin-film-transistor units; and

the first via-hole is filled with an organic material.

In the display module of the present application, the adjacent two thin-film-transistor units comprises the at least one first via-hole therebetween.

In the display module of the present application, the first via-hole is formed through the interlayer dielectric layer of the thin-film-transistor layer.

In the display module of the present application, the first via-hole is formed through the interlayer dielectric layer and the gate insulating layer of the thin-film-transistor layer.

In the display module of the present application, the display panel further comprises a non-display region outside the display region;

the non-display region comprises a bending region, wherein a first recess is formed in the bending region; and

the first recess and the first via-hole are formed in the same etching process.

In the display module of the present application, the first recess is formed by a first etching process and a second etching process;

the first etching process removes the interlayer dielectric layer, the second gate insulating layer and the first gate insulating layer in the first recess; and

the second etching process removes the buffer layer and the stop layer.

The beneficial effects of the present application are the bending stresses to the display panel can be reduced and the quality of the display panel can be increased by forming of a plurality of first via holes in the inorganic layer of the display panel and filling flexible materials in the first via holes.

### BRIEF DESCRIPTION OF DRAWINGS

To detailly explain the technical schemes of the embodiments or existing techniques, drawings that are used to illustrate the embodiments or existing techniques are provided.

Apparently, the illustrated embodiments are just a part of those of the present disclosure. It is easy for any person having ordinary skill in the art to obtain other drawings without labor for inventiveness.

FIG. 1 is a first structure of a display panel of the present application;

FIG. 2 is a second structure of a display panel of the present application;

FIG. 3 is a flowchart of a method for fabricating a display panel of the present application; and

FIGS. 4A-4E are schematic diagrams showing process steps of a method for fabricating a display panel of the present application.

### DETAILED DESCRIPTION

The following description of the various embodiments is provided to illustrate the specific embodiments. Directional terms mentioned in this application, such as “upper”, “lower”, “front”, “rear”, “left”, “right”, “inside”, “outside”, “side”, etc., are only illustrations of the drawings. Therefore, the directional terminology is used for the purpose of illustration and understanding, but not intended to be limiting. In the figures, elements of similar structures are assigned with the same reference numerals.

The present application provides a display panel 100, and the display panel 100 comprises a display region 200 and a non-display region 300 outside the display region 200. At least two pixel units are disposed in the display region 200, and at least one first via hole 22 is disposed between the adjacent two pixel units. The first via hole 22 is disposed in an inorganic layer of the display panel 100, and the first via-hole 22 is filled with an organic material.

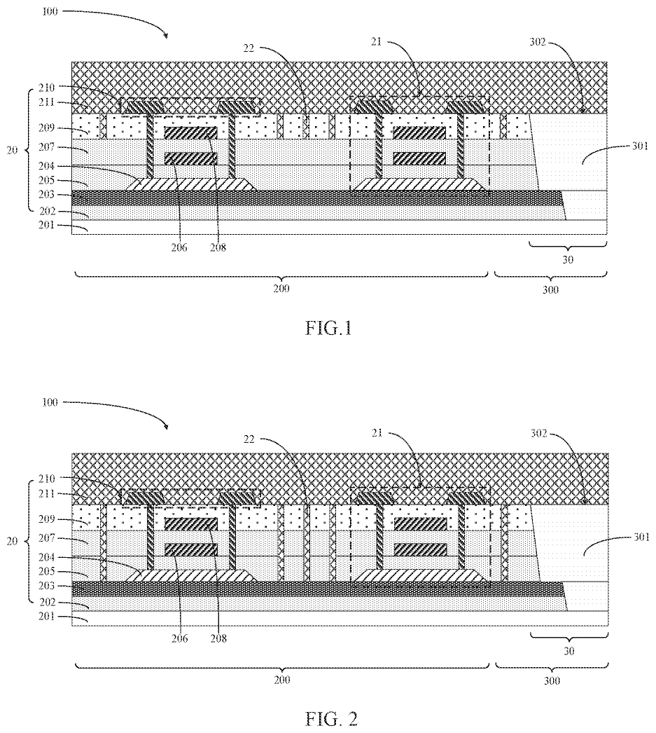

Referring to FIG. 1, FIG. 1 is a first structure of the display panel 100 of the present application.

A substrate 201 and a thin-film-transistor layer 20 are disposed over the substrate 201 disposed in the display region 200. The thin-film-transistor layer 20 comprises at least two thin-film-transistor units 21.

In the present embodiment, the substrate 201 may be one of a glass substrate, a quartz substrate, and a resin substrate.

In the present embodiment, the substrate 201 may be a flexible substrate. The flexible substrate may comprise polyimide.

In the present embodiment, one of the two thin-film-transistor units 21 corresponds to one of the pixel units. The first via-holes 22 of the present application are disposed between the two thin-film-transistor units 21.

In the present embodiment, the adjacent two thin-film-transistor units 21 comprises the at least one first via-hole 22 therebetween.

The thin-film-transistor layer 20 may comprise an etching stop layer 202, a back channel etched type or top-gate thin film transistor structure, and is not limited thereto. For example, the thin-film-transistor layer 20 of the top-gate thin film transistor structure may comprise a stop layer 202, a buffer layer 203, an active layer 204, a first gate insulating layer 205, a first metal layer 206, and second gate insulating layer 207, a second metal layer 208, an interlayer dielectric layer 209, a third metal layer 210 and a planarization layer 211. In the present embodiment, the first metal layer 206 and the second metal layer 208 can be named as a gate layer, and the first gate insulating layer 205 and the second gate insulating layer 207 can be named as a gate insulating layer.

The stop layer 202 is disposed over the substrate 201.

In the present embodiment, the stop layer 202 may comprise silicon oxide.

The buffer layer 203 is formed over the stop layer 202 to mainly buffering the stress between films and is able to block moisture.

In the present application, the buffer layer 203 may comprise one or more compounds of silicon nitride or silicon oxide.

The active layer 204 is formed over the buffer layer 203, and the active layer 204 comprises doping areas doped by ions.

The first gate insulating layer is formed over the active layer 204. The gate insulating layer 205 encapsulates the active layer 204, and the first gate insulating layer 205 is mainly used to isolate the active layer 204 from the metal layer formed over the active layer 204.

The first metal layer 206 is disposed over the first gate insulating layer 205.

The first metal layer 206 is the gate electrode of the display panel 100. The metal material for the gate electrode may use one of molybdenum, aluminum, aluminum-nickel alloy, molybdenum-tungsten alloy, chromium, or copper, and may use a compound of the above materials.

In the present embodiment, the metal material of the first metal layer 206 can be molybdenum.

The second gate insulating layer 207 is formed over the first metal layer 206. The second gate insulating layer 207 is mainly used to isolate the first metal layer 206 from the second metal layer 208.

In the present embodiment, materials of the first gate insulating layer 205 and the second gate insulating layer 207 can be inorganic materials such as silicon nitride, silicon oxide, or silicon oxynitride.

The second metal layer 208 is formed over the second gate insulating layer 207.

In the present embodiment, the metal material of the second metal layer 208 is the same with the metal material of the first metal layer 206.

The interlayer dielectric layer 209 is formed over the second metal layer 208, and the interlayer dielectric layer encapsulates the second metal layer 208 to isolate the second metal layer 208 from the third metal layer 210.

In the present embodiment, the material of the interlayer dielectric layer 209 can be the same with the materials of the first gate insulating layer 205 and the second gate insulating layer 207.

The third metal layer 210 is formed over the interlayer dielectric layer 209.

The third metal layer 210 is the source/drain electrode of the display panel 100. The material of the source/drain electrode may use one of molybdenum, aluminum, aluminum-nickel alloy, molybdenum-tungsten alloy, chromium, copper, or titanium-aluminum alloy, and may use a compound of the above material.

In the present embodiment, the third metal layer 210 is electrically connected with the active layer 204 through the second via hole.

In the present embodiment, the material of the third metal layer 210 may be the titanium-aluminum alloy.

The planarization layer 211 is formed over the third metal layer 210 to ensure the planarity of the film structure of the array substrate.

The display panel further comprises light-emitting device layers (not shown) and packaging layers (not shown) formed over the planarization layer 211.

Referring to FIG. 1, the first via holes 22 are formed in the interlayer dielectric layer 209.

In the present embodiment, a plurality of the first via holes 22 are formed in the adjacent thin-film transistor units 21, and the first via holes 22 are formed through the interlayer dielectric layer 209.

In the present embodiment, the first via holes 22 are filled with organic materials.

In the present embodiment, the material in the first via holes 22 is the same with the material of the planarization layer 211.

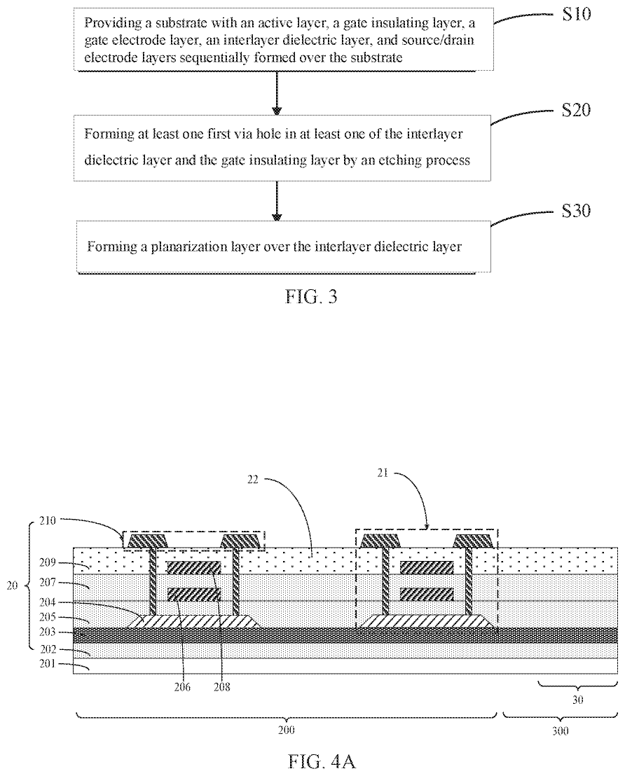

Referring to FIG. 2, FIG. 2 is a second structure of the display panel 100 of the present application.

The second via holes 22 are disposed in the interlayer dielectric layer 209 and the gate insulating layer. The gate insulating layer comprises the first gate insulating layer 205 and the second gate insulating layer 207.

In the present embodiment, the first via holes 22 are formed through the interlayer dielectric layer 209, the first gate insulating layer 205, and the second gate insulating layer 207.

A bending region 30 is disposed in the non-display region 300 in the display panel 100 of the present application. The bending region 30 is at a side of the display region 200.

A substrate 201 and a flexible layer 301 over the substrate 201 are disposed in the bending region 30.

In the present embodiment, the flexible layer 301 is disposed in the first recess 302.

The first recess 302 is formed by a first etching process and a second etching process.

The first etching process removes the interlayer dielectric layer 209, the second gate insulating layer 207, and the first gate insulating layer 205 in the first recess 302.

The second etching process removes the buffer layer 203 and the stop layer 202.

Since the first via holes 22 of the present embodiment are formed through the interlayer dielectric layer 209, the first gate insulating layer 205, and the second gate insulating layer 207, so that the first via hole 11 can be formed by the same first etching process.

In the present embodiment, the first etching process and the second etching process may be dry etching.

In the present embodiment, the first via holes 22 may be disposed in the stop layer 202, the buffer layer 203, the first gate insulating layer 205, the second gate insulating layer 207, and the interlayer dielectric layer 209. The first via holes 22 are formed through the stop layer 202, the buffer layer 203, the gate insulating layer 205, the second gate insulating layer 207, and the interlayer dielectric layer 209.

In the present embodiment, the first via holes 22 may be further etched by the second etching process and no additional etching process is needed, thereby increasing process efficiency and reducing producing costs.

In the above embodiment, the first via holes 22 are filled with organic materials. The bending stress of the display panel 100 can be reduced, and stress concentration at the inorganic layer can be released, thereby improving the quality of the display panel 100.

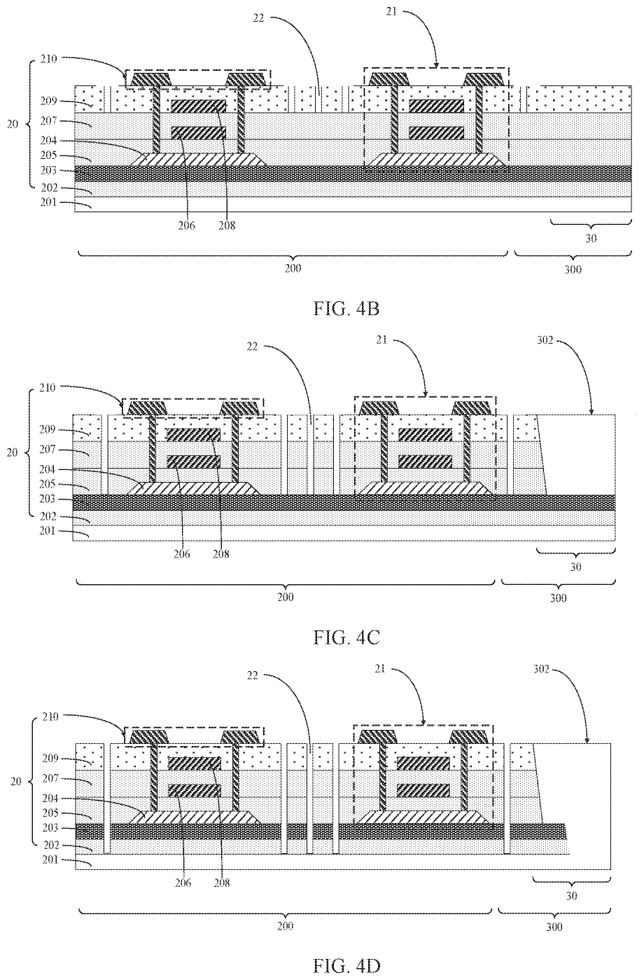

Referring to FIG. 3, FIG. 3 is a flowchart of a method for fabricating the display panel 100 of the present application.

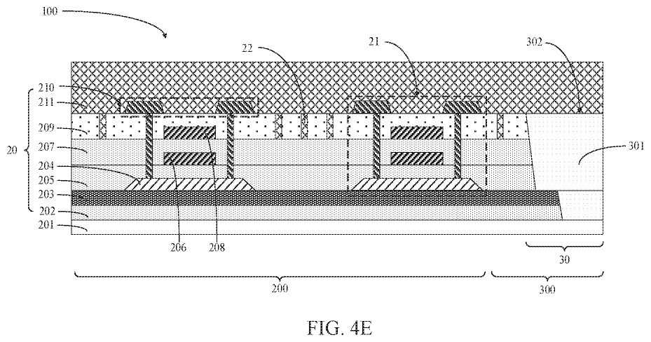

Referring to FIGS. 4A-4E, FIGS. 4A-4E are diagrams showing process steps of the method for fabricating the display panel 100 of the present application.

The method for fabricating the display panel 100 comprises:

S10: providing a substrate 201 with an active layer 204, a gate insulating layer, a gate electrode layer, an interlayer dielectric layer 209, and source/drain electrode layers sequentially formed over the substrate 201.

Referring to FIG. 4A, a stop layer 202, a buffer layer 204, an active layer 204, a first gate insulating layer 206, a first metal layer 206, a second gate insulating layer 207, a second metal layer 208, and an interlayer dielectric layer 209 are sequentially formed over the substrate 201. The first metal layer 206 and the second metal layer 208 may be named as a gate electrode layer, and the first gate insulating layer 205 and the second gate insulating layer 207 may be named as a gate insulating layer.

In the present embodiment, the substrate 201 can be one of a glass substrate, a quartz substrate, and a resin substrate.

In the present embodiment, the substrate 201 can be a flexible substrate. The flexible substrate may comprise polyimide.

The stop layer 202 is disposed over the substrate 201.

In the present embodiment, the stop layer 202 may comprise silicon oxide.

The buffer layer 203 is formed over the stop layer 202 to mainly buffering the stress between films and is able to block moisture.

In the present application, the buffer layer 203 may comprise one or more compounds of silicon nitride or silicon oxide.

The active layer 204 is formed over the buffer layer 203.

The first gate insulating layer 205 is formed over the active layer 204. The gate insulating layer 205 encapsulates the active layer 204, and the first gate insulating layer 205 is mainly used to isolate the active layer 204 from the metal layer formed over the active layer 204.

The first metal layer 206 is disposed over the first gate insulating layer 205.

The first metal layer 206 is the gate electrode of the display panel 100. The metal material for the gate electrode may use one of molybdenum, aluminum, aluminum-nickel alloy, molybdenum-tungsten alloy, chromium, or copper, and may use a compound of the above materials.

In the present embodiment, the metal material of the first metal layer 206 can be molybdenum.

The second gate insulating layer 207 is formed over the first metal layer 206. The second gate insulating layer 207 is mainly used to isolate the first metal layer 206 from the second metal layer 208.

In the present embodiment, materials of the first gate insulating layer 205 and the second gate insulating layer 207 can be inorganic materials such as silicon nitride, silicon oxide, or silicon oxynitride.

The second metal layer 208 is formed over the second gate insulating layer 207.

In the present embodiment, the metal material of the second metal layer 208 is the same with the metal material of the first metal layer 206.

The interlayer dielectric layer 209 is formed over the second metal layer 208, and the interlayer dielectric layer encapsulates the second metal layer 208 to isolate the second metal layer 208 from the third metal layer 210.

In the present embodiment, the material of the interlayer dielectric layer 209 can be the same with the materials of the first gate insulating layer 205 and the second gate insulating layer 207.

Referring to FIG. 4A, the third metal layer 210 is formed over the interlayer dielectric layer 209.

The third metal layer 210 is the source/drain electrode of the display panel 100. The material of the source/drain electrode may use one of molybdenum, aluminum, aluminum-nickel alloy, molybdenum-tungsten alloy, chromium, copper or titanium-aluminum alloy, and may use a compound of the above materials.

In the present embodiment, the third metal layer 210 is electrically connected with the active layer 204 through the second via hole.

In the present embodiment, the material of the third metal layer 210 can be titanium-aluminum alloy.

S20: forming at least one first via hole 22 in at least one of the interlayer dielectric layer 209 and the gate insulating layer by an etching process;

Referring to FIG. 4B, the first via hole 22 is formed in the interlayer dielectric layer 209.

In the present step, a plurality of the first via holes 22 are disposed in the adjacent thin-film transistor units 21, and the first via holes 22 are formed through the interlayer dielectric layer 209.

Referring to FIG. 4C, the first via holes 22 are formed in the interlayer dielectric layer 209 and the gate insulating layer. The gate insulating layer comprises the first gate insulating layer 205 and the second gate insulating layer 207.

In the present embodiment, the first via holes 22 are formed through the interlayer dielectric layer 209, the first gate insulating layer 205 and the second gate insulating layer 207.

A bending region 30 is disposed in the non-display region 300 in the display panel 100 of the present application. The bending region 30 is at a side of the display region 200.

In the present step, the first recess 302 is formed in the bending region 30 and the plurality of first via holes 22 are formed in the display region 200 by an etching process.

The first recess 302 is formed by a first etching process and a second etching process.

The first etching process removes the interlayer dielectric layer 209, the second gate insulating layer 207, and the first gate insulating layer 205 in the first recess 302. The second etching process removes the buffer layer 203 and the stop layer 202.

In the present embodiment, since the first via holes 22 of the present embodiment are formed through the interlayer dielectric layer 209, the first gate insulating layer 205, and the second gate insulating layer 207, so that the first via holes 22 can be formed by the same first etching process.

In the present embodiment, the first etching process and the second etching process can be dry etching.

Referring to FIG. 4D, the first via holes 22 may be disposed in the stop layer 202, the buffer layer 203, the first gate insulating layer 205, the second gate insulating layer 207, and the interlayer dielectric layer 209. The first via holes 22 are formed through the stop layer 202, the buffer layer 203, the gate insulating layer 205, the second gate insulating layer 207, and the interlayer dielectric layer 209.

In the present embodiment, the first etching process and the second etching process can be dry etching.

The present step further comprises:

filling flexible materials in the first recess 302 to form a flexible layer 301.

S30: forming the planarization layer 211 over the interlayer dielectric layer 209.

Referring to FIG. 4E, one of the three embodiments described above is used for illustration.

The planarization layer 211 is formed over the third metal layer 210 to ensure the planarity of the film structure of the array substrate.

In the present embodiment, the first via holes 22 are filled with organic material the same with that of the planarization layer 211.

Finally, the process steps for forming the light-emitting device layer (not shown) and the packaging layer (not shown) are performed.

An embodiment of the present application further provides a display module, comprising a display panel, and a polarizing layer and a covering layer disposed above the display panel. Operation of the display module is the same or similar with the display panel and are not described in the present application.

The present application provides a display panel, a display module, and a fabrication method thereof. The display panel comprises a display region, wherein at least two pixel units are disposed in the display region, and at least one first via hole is disposed between the adjacent two pixel units; and the first via hole is disposed in an inorganic layer of the display panel, and the first via holes are filled with flexible materials to reduce the bending stresses to the display panel and increase the quality of the display panel.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

1. A display panel, comprising a display region;
wherein at least two pixel units are disposed in the display region, and at least one first via hole is disposed between the adjacent two pixel units; and
the first via hole is disposed in an inorganic layer of the display panel.

2. The display panel as claimed in claim 1, wherein:
a substrate and a thin-film-transistor layer are disposed over the substrate disposed in the display region;
the thin-film-transistor layer comprises at least two thin-film-transistor units;
the two thin-film-transistor units respectively correspond to the pixel units;
the first via-hole is disposed between the two thin-film-transistor units; and
the first via-hole is filled with an organic material.

3. The display panel as claimed in claim 2, wherein:
the adjacent two thin-film-transistor units comprises the at least one first via-hole therebetween.

4. The display panel as claimed in claim 2, wherein:
the thin-film-transistor layer further comprises an interlayer dielectric layer; and
the first via-hole is formed through the interlayer dielectric layer of the thin-film-transistor layer.

5. The display panel as claimed in claim 2, wherein:
the thin-film-transistor layer further comprises an interlayer dielectric layer and a gate insulating layer; and
the first via-hole is formed through the interlayer dielectric layer and the gate insulating layer of the thin-film-transistor layer.

6. The display panel of claim 1, wherein:
the display panel further comprises a non-display region outside the display region;
the non-display region comprises a bending region, wherein a first recess is formed in the bending region; and
the first recess and the first via-hole are formed in the same etching process.

7. The display panel as claimed in claim 1, wherein:
the thin-film-transistor layer further comprises a stop layer, a buffer layer, an interlayer dielectric layer and a gate insulating layer, and the gate insulating layer comprises a first gate insulating layer and a second gate insulting layer;
the first recess is formed by a first etching process and a second etching process;
the first etching process removes the interlayer dielectric layer, the second gate insulating layer and the first gate insulating layer in the first recess; and
the second etching process removes the buffer layer and the stop layer.

8. A method for fabricating a display panel, comprising:
providing a substrate, wherein an active layer, a gate insulating layer, a gate electrode layer, an interlayer dielectric layer, and a source/drain electrode layer are sequentially formed over the substrate;
performing an etching process to form at least one via-hole in at least one of the interlayer dielectric layer and the gate insulating layer;
forming a planarization layer over the interlayer dielectric layer;
wherein the first via-hole is disposed between adjacent two pixel units of the display panel.

9. The method as claimed in claim 8, wherein:
the display panel comprises a non-display region;
the non-display region comprises a bending region, and a first recess is disposed in the bending region; and
a flexible organic material is filled in the first recess.

10. The method as claimed in claim 9, wherein:
the first via-hole is formed through the interlayer dielectric layer as the first via-hole is formed above the interlayer dielectric layer, and the first via-hole and the first recess are formed by different etching processes.

11. The method as claimed in claim 9, wherein:
the first via-hole is formed through the interlayer dielectric layer and the gate insulating layer as the first via-hole is formed above the interlayer dielectric layer and the gate insulating layer, and the first via-hole and the first recess are formed in the same etching process.

12. The method as claimed in claim 8, wherein:
the display panel comprises a substrate and a thin-film-transistor layer disposed over the substrate;
the thin-film-transistor layer comprises at least two thin-film-transistor units;
the two thin-film-transistor units respectively correspond to the pixel elements;
the first via-hole is disposed between the two thin-film-transistor units; and
the first via-hole is filled with a flexible material.

13. The method as claimed in claim 8, wherein:
a stop layer and a buffer layer are further formed between the substrate and the active layer, and the gate insulating layer comprises a first gate insulating layer and a second gate insulating layer sequentially formed over substrate;
the first recess is formed by a first etching process and a second etching process;
the first etching process removes the interlayer dielectric layer, the second gate insulating layer and the first gate insulating layer in the first recess; and
the second etching process removes the buffer layer and the stop layer.

14. A display module, comprising a display panel, and a polarizing layer and a covering layer disposed above the display panel, wherein the display panel comprises a display region;
at least two pixel units are disposed in the display region, and
at least one first via hole is disposed between the adjacent two pixel elements, wherein the first via hole is disposed in an inorganic layer of the display panel.

15. The display module as claimed in claim 14, wherein:
a substrate and a thin-film-transistor layer disposed over the substrate are disposed in the display region;
the thin-film-transistor layer comprises at least two thin-film-transistor units;
the two thin-film-transistor units respectively correspond to the pixel units;
the first via-hole is disposed between the two thin-film-transistor units; and
the first via-hole is filled with an organic material.

16. The display module as claimed in claim 15, wherein:
the adjacent two thin-film-transistor units comprises the at least one first via-hole therebetween.

17. The display module as claimed in claim 15, wherein:
the thin-film-transistor layer further comprises an interlayer dielectric layer; and
the first via-hole is formed through the interlayer dielectric layer of the thin-film-transistor layer.

18. The display module as claimed in claim 15, wherein:
the thin-film-transistor layer further comprises an interlayer dielectric layer and a gate insulating layer; and
the first via-hole is formed through the interlayer dielectric layer and the gate insulating layer of the thin-film-transistor layer.

19. The display module as claimed in claim 14, wherein:
the display panel further comprises a non-display region outside the display region;
the non-display region comprises a bending region, wherein a first recess is formed in the bending region; and
the first recess and the first via-hole are formed in the same etching process.

20. The display module as claimed in claim 14, wherein:
the first recess is formed by a first etching process and a second etching process;
the first etching process removes the interlayer dielectric layer, the second gate insulating layer and the first gate insulating layer in the first recess; and
the second etching process removes the buffer layer and the stop layer.
